(19) United States
(12) Patent Application Publication
(10) Pub. No.: US 2022/0293812 A1
(43) Pub. Date: Sep. 15, 2022

(54) Photoelectric Detection Substrate, Preparation Method Thereof and Photoelectric Detection Apparatus

(71) Applicant: BOE Technology Group Co., Ltd., Beijing (CN)

(72) Inventor: Rui HUANG, Beijing (CN)

(21) Appl. No.: 17/512,688

(22) Filed: Oct. 28, 2021

(30) Foreign Application Priority Data
Mar. 12, 2021 (CN) 202110272422.4

(51) Int. Cl. H01L 31/108; H01L 31/18

(52) U.S. Cl. CPC H01L 31/108; H01L 31/1812

(57) ABSTRACT

A photoelectric detection substrate, a preparation method thereof and a photoelectric detection apparatus are provided. The photoelectric detection substrate includes a glass substrate, and an electronic apparatus and an optical apparatus disposed on the glass substrate, wherein the optical apparatus is a Schottky photo-diode. The Schottky photo-diode includes a first electrode, an ohmic contact layer disposed on one side of the first electrode away from the glass substrate, an intrinsic layer disposed on one side of the ohmic contact layer away from the glass substrate and a second electrode disposed on one side of the intrinsic layer away from the glass substrate.

### CROSS-REFERENCE TO RELATED APPLICATION

The present application claims the priority of Chinese Patent Application No. 202110272422.4 filed to the CNIPA on Mar. 12, 2021, the content of which is hereby incorporated by reference.

### TECHNICAL FIELD

The present disclosure relates to, but is not limited to, the field of optoelectronic technologies, in particular to a photoelectric detection substrate, a preparation method thereof and a photoelectric detection apparatus.

### BACKGROUND

Photoelectric sensors may be used in fingerprint identification, medical detection and other fields, and play an increasingly significant role in the national economy and people's livelihood. For example, fingerprint identification of display apparatuses (such as laptop computers, tablet computers, mobile phones, etc.) is implemented by the photoelectric sensors that use the refraction and reflection of light to perform imaging of users' fingerprints.

The current mass-produced optical fingerprint module is a single-fingered silicon-based CMOS (Complementary Metal Oxide Semiconductor) detector. Due to the manufacturing cost and process difficulty of semiconductor apparatuses, it is difficult for the silicon-based CMOS fingerprint module to develop under a large screen. On the other hand, glass-based photoelectric detection substrates have the advantages of large area fabrication, simple process and low cost, and thus have a good application prospect in fingerprint identification of display apparatuses.

Nowadays, the glass-based photoelectric detection substrate includes a plurality of pixels forming a sensing array, and each pixel includes an optical apparatus and an electronic apparatus, wherein the optical apparatus may include a Photo-Diode (PD) and the electronic apparatus may include a Thin Film Transistor (TFT), and the photo-diode converts an optical signal into an electrical signal, which is addressed and output through the TFT. However, in practical application, there is a problem of low performance of photo-diodes.

### SUMMARY

The following is a summary of the subject matters described in the present disclosure in detail. This brief description is not intended to limit the scope of protection of the claims.

An embodiment of the disclosure provides a photoelectric detection substrate including a glass substrate, and an electronic apparatus and an optical apparatus disposed on the glass substrate, wherein the optical apparatus is a Schottky photo-diode.

In an exemplary embodiment, the Schottky photo-diode includes a first electrode, an ohmic contact layer disposed on one side of the first electrode away from the glass substrate, an intrinsic layer disposed on one side of the ohmic contact layer away from the glass substrate and a second electrode disposed on one side of the intrinsic layer away from the glass substrate; or, the Schottky photo-diode includes a first electrode, an intrinsic layer disposed on one side of the first electrode away from the glass substrate, an ohmic contact layer disposed on one side of the intrinsic layer away from the glass substrate, and a second electrode disposed on one side of the ohmic contact layer away from the glass substrate.

In an exemplary embodiment, the Schottky photo-diode includes a first electrode, an ohmic contact layer disposed on one side of the first electrode away from the glass substrate, an intrinsic layer disposed on one side of the ohmic contact layer away from the glass substrate, a barrier layer disposed on one side of the intrinsic layer away from the glass substrate and a second electrode disposed on one side of the barrier layer away from the glass substrate; or, the Schottky photo-diode includes a first electrode, a barrier layer disposed on one side of the first electrode away from the glass substrate, an intrinsic layer disposed on one side of the barrier layer away from the glass substrate, an ohmic contact layer disposed on one side of the intrinsic layer away from the glass substrate, and a second electrode disposed on one side of the ohmic contact layer away from the glass substrate.

In an exemplary embodiment, the Schottky photo-diode includes a first electrode, a first barrier layer disposed on one side of the first electrode away from the glass substrate, an intrinsic layer disposed on one side of the first barrier layer away from the glass substrate, a second barrier layer disposed on one side of the intrinsic layer away from the glass substrate, and a second electrode disposed on one side of the second barrier layer away from the glass substrate.

In an exemplary embodiment, the material of the first electrode includes molybdenum, aluminum, copper, lead or gold, the material of the second electrode includes indium tin oxide or indium zinc oxide, the material of the ohmic contact layer includes N-type doped amorphous silicon, N-type doped microcrystalline silicon or N-type doped silicon germanium alloy, and the material of the intrinsic layer includes amorphous silicon, microcrystalline silicon or silicon germanium alloy.

In an exemplary embodiment, and the material of the barrier layer includes silicon oxide, silicon nitride, silicon oxynitride or aluminum oxide.

In an exemplary embodiment, and the thickness of the barrier layer is 1 nm to 5 nm.

In an exemplary embodiment, the electronic apparatus includes an oxide thin film transistor.

An embodiment of the disclosure further provides a photoelectric detection apparatus, including any one of the aforementioned photoelectric detection substrates.

An embodiment of the present disclosure further provides a preparation method for a photoelectric detection substrate, including:

forming an electronic apparatus and an optical apparatus on a glass substrate, wherein the optical apparatus is a Schottky photo-diode.

In an exemplary embodiment, forming the Schottky photo-diode on the glass substrate includes:

forming a first electrode; and sequentially forming an ohmic contact layer, an intrinsic layer and a second electrode, wherein the ohmic contact layer is disposed on one side of the first electrode away from the glass substrate, the intrinsic layer is disposed on one side of the ohmic contact layer away from the glass substrate, and the second electrode is disposed on one side of the intrinsic layer away from the glass substrate; or

forming a first electrode; and sequentially forming an intrinsic layer, an ohmic contact layer and a second electrode; wherein the intrinsic layer is disposed on one side of the first electrode away from the glass substrate, the ohmic contact layer is disposed on one side of the intrinsic layer away from the glass substrate, and the second electrode is disposed on one side of the ohmic contact layer away from the glass substrate.

In an exemplary embodiment, forming the Schottky photo-diode on the glass substrate includes:

forming a first electrode; and sequentially forming an ohmic contact layer, an intrinsic layer, a barrier layer and a second electrode; wherein the ohmic contact layer is disposed on one side of the first electrode away from the glass substrate, the intrinsic layer is disposed on one side of the ohmic contact layer away from the glass substrate, the barrier layer is disposed on one side of the intrinsic layer away from the glass substrate, and the second electrode is disposed on one side of the barrier layer away from the glass substrate; or

forming a first electrode; and sequentially forming a barrier layer, an intrinsic layer, an ohmic contact layer and a second electrode; wherein the barrier layer is disposed on one side of the first electrode away from the glass substrate, the intrinsic layer is disposed on one side of the barrier layer away from the glass substrate, the ohmic contact layer is disposed on one side of the intrinsic layer away from the glass substrate, and the second electrode is disposed on one side of the ohmic contact layer away from the glass substrate.

In an exemplary embodiment, forming the Schottky photo-diode on the glass substrate includes:

forming a first electrode; and sequentially forming a first barrier layer, an intrinsic layer, a second barrier layer and a second electrode; wherein the first barrier layer is disposed on one side of the first electrode away from the glass substrate, the intrinsic layer is disposed on one side of the first barrier layer away from the glass substrate, the second barrier layer is disposed on one side of the intrinsic layer away from the glass substrate, and the second electrode is disposed on one side of the second barrier layer away from the glass substrate.

In an exemplary embodiment, the material of the first electrode includes molybdenum, aluminum, copper, lead or gold, the material of the second electrode includes indium tin oxide or indium zinc oxide, the material of the ohmic contact layer includes N-type doped amorphous silicon, N-type doped microcrystalline silicon or N-type doped silicon germanium alloy, and the material of the intrinsic layer includes amorphous silicon, microcrystalline silicon or silicon germanium alloy.

In an exemplary embodiment, the material of the barrier layer includes silicon oxide, silicon nitride, silicon oxynitride or aluminum oxide, the barrier layer is deposited by plasma enhanced chemical vapor deposition, atomic layer deposition, thermal oxidation or chemical oxidation; and the thickness of the barrier layer is 1 nm to 5 nm.

After reading and understanding the drawings and the detailed description, other aspects can be understood.

### BRIEF DESCRIPTION OF DRAWINGS

The drawings are used to provide an understanding of technical solutions of the present disclosure, form a part of the specification, and are used to explain, together with the embodiments of the present disclosure, the technical solutions of the present disclosure and are not intended to form limitations on the technical solutions of the present disclosure.

FIG. 1 is a schematic diagram of a structure of a photoelectric detection substrate in an exemplary embodiment of the present disclosure.

FIG. 2 is a schematic diagram after a pattern of a first metal layer is formed according to an exemplary embodiment of the present disclosure.

FIG. 3 is a schematic diagram after a pattern of a semiconductor layer is formed according to an exemplary embodiment of the present disclosure.

FIG. 4 is a schematic diagram after a pattern of a second metal layer is formed according to an exemplary embodiment of the present disclosure.

FIG. 5 is a schematic diagram after a pattern of a second insulating layer is formed according to an exemplary embodiment of the present disclosure.

FIG. 6 is a schematic diagram after a pattern of a third metal layer is formed according to an exemplary embodiment of the present disclosure.

FIG. 7 is a schematic diagram after a pattern of a photo-diode is formed according to an exemplary embodiment of the present disclosure.

FIG. 8 is a schematic diagram after patterns of a third insulating layer and a planarization layer are formed according to an exemplary embodiment of the present disclosure.

FIG. 9 is a schematic diagram of a display substrate after a pattern of a fourth insulating layer is formed according to an exemplary embodiment of the present disclosure.

FIG. 10 is another schematic diagram of a structure of a photoelectric detection substrate in an exemplary embodiment of the present disclosure.

FIG. 11 is another schematic diagram of a structure of a photoelectric detection substrate in an exemplary embodiment of the present disclosure.

FIG. 12 is another schematic diagram of a structure of a photoelectric detection substrate in an exemplary embodiment of the present disclosure.

FIG. 13 is another schematic diagram of a structure of a photoelectric detection substrate in an exemplary embodiment of the present disclosure.

FIG. 14 is a schematic diagram of carrier transport in a Metal-Insulator-Semiconductor (MIS) structure.

FIG. 15 is a comparison diagram of oxygen content between an MIS structure and a Schottky structure.

FIG. 16 is a comparison diagram of leakage current between an MIS structure and a Schottky structure.

### DETAILED DESCRIPTION

The embodiments of the present disclosure will be described below in detail with reference to the drawings. It should be noted that the embodiments may be implemented in a number of different forms. It is easy for those skilled in the art to understand the fact that the form and content may be changed into various forms without departing from the purpose and scope of the present disclosure. Therefore, the present disclosure should not be interpreted as limited to the content recorded in the following embodiments. Without conflict, the embodiments in the present disclosure and the features in the embodiments may be freely combined with each other.

In the drawings, the size of each constituent element, or the thickness or area of a layer, is sometimes exaggerated for clarity. Therefore, an implementation of the present disclosure is not necessarily limited to the size shown, and a shape and size of each component in the drawings do not reflect true proportions. In addition, the drawings schematically illustrate ideal examples, and a mode of the present disclosure is not limited to the shapes, numerical values, or the like shown in the drawings.

“First”, “second”, “third” and other ordinal numerals in the specification are set to avoid the confusion of the constituent elements, rather than to limit the quantity.

For convenience, in the specification the terms such as “middle”, “up”, “down”, “front”, “back”, “vertical”, “horizontal”, “top”, “bottom”, “inside” and “outside” indicating the orientation or position relationship are used to describe the position relationship between the constituent elements with reference to the drawings, only for the convenience of describing the specification and simplifying the description, instead of indicating or implying that the apparatus or element referred to must have a specific orientation or be constructed and operated in a specific orientation, so they should not be understood as limitations to the present disclosure. The positional relations of each of the constituent elements may be appropriately changed according to the direction in which constituent elements are described. Therefore, appropriate replacements based on situations are allowed, not limited to the expressions in the specification.

Unless otherwise specified and limited, in the specification the terms “mount”, “connected” and “connect” should be understood in a broad sense. For example, it may be fixed connection, removable connection, or integrated connection; it may be mechanical connection or electrical connection; it may be direct connection, indirect connection through an intermediate component, or communication inside two components. For those skilled in the art, the meaning of the above terms in the present disclosure may be understood according to the situation.

In the specification, a transistor refers to a component which at least includes three terminals, i.e., a gate electrode, a drain electrode and a source electrode. The transistor has a channel region between the drain electrode (drain electrode terminal, drain region, or drain electrode) and the source electrode (source electrode terminal, source region, or source electrode), and a current may flow through the drain electrode, the channel region, and the source region. It should be noted that the channel region herein refers to the region where the current mainly flows.

In the specification, a first electrode may be a drain electrode and a second electrode may be a source electrode, or a first electrode may be a source electrode and a second electrode may be a drain electrode. In cases that transistors with opposite polarities are used, or a current direction changes during work of a circuit, or the like, functions of the “source electrode” and the “drain electrode” may sometimes be exchanged. Therefore, “source electrode” and “drain electrode” may be exchanged with each other in the specification.

In this specification, an “electrical connection” includes a case where constituent elements are connected together through an element with a certain electric action. “The element with the certain electric action” is not particularly limited as long as electric signals between the connected composition elements may be sent and received. Examples of the “element with a certain electric action” include not only electrodes and wirings, but also switching elements such as transistors, resistors, inductors, capacitors, and other elements having various functions.

In this specification, “parallel” refers to a state in which two straight lines form an angle between −10 degrees and 10 degrees and thus, includes a state in which the angle is between −5 degrees and 5 degrees. In addition, “perpendicular” refers to a state in which an angle formed by two straight lines is above 80 degrees and below 100 degrees, and thus may include a state in which an angle is above 85 degrees and below 95 degrees.

In this specification, “film” and “layer” may be interchangeable. For example, “conductive layer” may be replaced with “conductive film” sometimes. Similarly, “insulating film” may be replaced with “insulating layer” sometimes.

In the present disclosure, “about” refers to a numerical value within a range of allowable process and measurement errors without strictly limiting the limit.

The existing structure has the problem of low performance of photo-diode, which is caused by the structure of photo-diode. In the existing glass-based photoelectric detection substrate, the photo-diode often adopts PIN photo-diode, which includes P-type semiconductor (P layer), N-type semiconductor (N layer) and intrinsic semiconductor (intrinsic layer) sandwiched between them. P layer in PIN photo-diode will absorb part of light, especially short-band light, resulting in large absorption loss, thus reducing the performance of photo-diode. In the preparation of PIN photo-diode, it is necessary to use diborane (B2H6) process to form the P layer, and boron (B) ions generated in the diborane process will remain in the chamber, which will make the amorphous silicon formed later doped, thus reducing the performance of the photo-diode. Although the problem of B ion residue may be improved by cleaning the chamber, frequent cleaning of the chamber will affect the productivity, reduce the production efficiency and increase the production cost.

The present disclosure provides a photoelectric detection substrate. In an exemplary embodiment, the photoelectric detection substrate may include a glass substrate, and an electronic apparatus and an optical apparatus disposed on the glass substrate, wherein the optical apparatus is a Schottky photo-diode without a P layer.

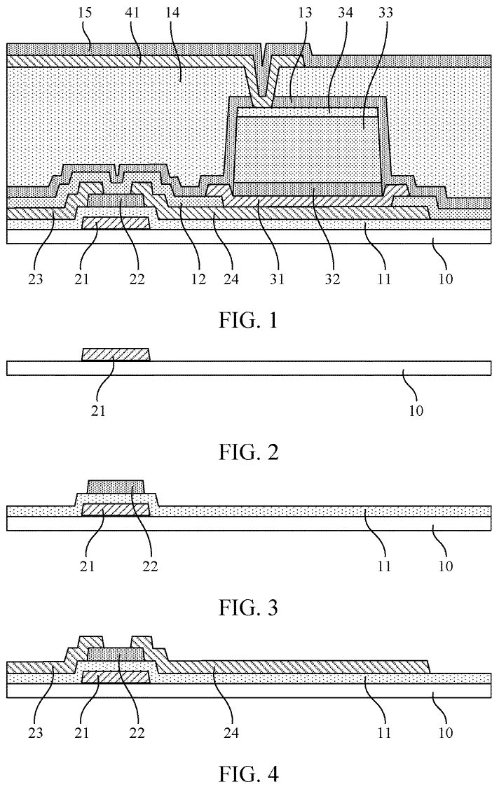

FIG. 1 is a schematic diagram of a structure of a photoelectric detection substrate in an exemplary embodiment of the present disclosure. As shown in FIG. 1, the photoelectric detection substrate includes a glass substrate 10 and an optical apparatus and an electronic apparatus disposed on the glass substrate 10. In an exemplary embodiment, the optical apparatus may be a Schottky photo-diode without a P layer, and the electronic apparatus may be a thin film transistor. Schottky photo-diode may include a first electrode 31, an ohmic contact layer 32, an intrinsic layer 33 and a second electrode 34 disposed in sequence along the direction perpendicular to the glass substrate, wherein the ohmic contact layer 32 is disposed on one side of the first electrode 31 away from the glass substrate, the intrinsic layer 33 is disposed on one side of the ohmic contact layer 32 away from the glass substrate, and the second electrode 34 is disposed on one side of the intrinsic layer 33 away from the glass substrate.

In an exemplary embodiment, the first electrode 31 may be made of a metal material with high work function, such as molybdenum, aluminum, copper, lead or gold, the ohmic contact layer 32 may be made of an N-doped silicon-based semiconductor such as N-doped amorphous silicon, doped microcrystalline silicon or doped silicon-germanium alloy, the intrinsic layer 33 may be made of a silicon-based semiconductor such as amorphous silicon, microcrystalline silicon or silicon-germanium alloy, and the second electrode 34 may be made of a transparent conductive metal oxide material with high work function. The thin film transistor may include a gate electrode 21, an active layer 22, a source electrode 23 and a drain electrode 24, both of the source electrode 23 and the drain electrode 24 are connected to the active layer 22, and the active layer 22 may be made of oxide.

In an exemplary embodiment, the photoelectric detection substrate further includes a first insulating layer 11, a second insulating layer 12, a third insulating layer 13, and a planarization layer 14; the first insulating layer 11 covers a gate electrode 21 of a thin film transistor, an active layer 22, a source electrode 23 and a drain electrode 24 of the thin film transistor are disposed on the first insulating layer 11, the second insulating layer 12 covers the thin film transistor, a first opening exposing the drain electrode 24 is provided on the second insulating layer 12, a first electrode 31 of the photo-diode is disposed on the second insulating layer 12 and is connected to the drain electrode 24 of the thin film transistor through the first opening; an ohmic contact layer 32 is disposed on the first electrode 31, an intrinsic layer 33 is disposed on the ohmic contact layer 32, and a second electrode 34 is disposed on the intrinsic layer 33; the third insulating layer 13 covers the first electrode 31, the ohmic contact layer 32, the intrinsic layer 33 and the second electrode 34 of the photo-diode, the planarization layer 14 covers the third insulating layer 13, a second opening is provided on the third insulating layer 13 and the planarization layer 14, and the second opening exposes the second electrode 34.

In an exemplary embodiment, the photoelectric detection substrate further includes an electrode lead 41 disposed on the planarization layer 14 and connected to the second electrode 34 through the second opening.

In an exemplary embodiment, the photoelectric detection substrate further includes a fourth insulating layer 15 covering the electrode lead 41.

In an exemplary embodiment, the ohmic contact layer 32, the intrinsic layer 33, and the second electrode 34 of the photo-diode may be simultaneously formed through a same patterning process.

The following is an exemplary explanation through a preparation process of the photoelectric detection substrate. “Patterning process” mentioned in the present disclosure includes photoresist coating, mask exposure, development, etching, photoresist stripping and so on for metal materials, inorganic materials or transparent conducting materials, and includes organic material coating, mask exposure, development and so on for organic materials. Deposition may be implemented by adopting any one or more of sputtering, evaporation and chemical vapor deposition. Coating may be implemented by adopting any one or more of spray coating, spin coating and inkjet printing, and etching may be implemented by adopting any one or more of dry etching and wet etching, which are not limited in the present disclosure. “Thin film” refers to a layer of thin film formed by a certain material on a base through deposition, coating or other processes. If a “thin film” does not need a patterning process in the whole preparing process, the “thin film” may also be called a “layer”. If a “thin film” needs a patterning process in the whole preparing process, it is called “thin film” before the patterning process and “layer” after the patterning process. A “layer” obtained after a patterning process includes at least one “pattern”. “A and B are disposed in the same layer” in the present disclosure means that A and B are formed at the same time through the same patterning process, and the “thickness” of the film layer is the size of the film layer in a direction perpendicular to the display substrate. In an exemplary embodiment of the present disclosure, “an orthographic projection of A contains an orthographic projection of B” means that the boundary of the orthographic projection of B falls within the boundary range of the orthographic projection of A, or the boundary of the orthographic projection of A is overlapped with the boundary of the orthographic projection of B.

In an exemplary embodiment, the preparation process of the photoelectric detection substrate may include the following operations:

(1) A pattern of a first metal layer is formed. In an exemplary embodiment, forming a pattern of a first metal layer may include: depositing a first metal thin film on a glass substrate, and patterning the first metal thin film through a patterning process to form a pattern of the first metal layer, wherein the pattern of the first metal layer at least includes a gate electrode 21, as shown in FIG. 2.

In an exemplary embodiment, the pattern of the first metal layer may include a scan signal line, and the gate electrode may be an integral structure interconnected with the scan signal line.

In an exemplary embodiment, the glass substrate may be made of materials such as glass or quartz.

(2) A pattern of a semiconductor layer is formed. In an exemplary embodiment, forming a pattern of a semiconductor layer may include: sequentially depositing a first insulating film and a semiconductor thin film on the glass substrate on which the aforementioned patterns are formed, and patterning the semiconductor thin film through a patterning process to form a first insulating layer 11 covering the pattern of the first metal layer and a pattern of the semiconductor layer disposed on the first insulating layer 11, wherein the pattern of the semiconductor layer at least includes the first active layer 22, as shown in FIG. 3.

In an exemplary embodiment, the semiconductor thin film may use oxide, and the formed active layer is an oxide active layer to form an oxide thin film transistor.

In an exemplary embodiment, the semiconductor thin film may alternatively be amorphous silicon or polysilicon, and this disclosure is not limited here.

(3) A pattern of a second metal layer is formed. In an exemplary embodiment, forming a pattern of a second metal layer may include: depositing a second metal thin film on the glass substrate on which the aforementioned patterns are formed, and patterning the second metal thin film through a patterning process to form a pattern of a second metal layer, wherein the pattern of the second metal layer at least includes a source electrode 23 and a drain electrode 24, wherein one end of the source electrode 23 and one end of the drain electrode 24 close to each other are laid on the active layer 22, and a conductive channel is formed between the source electrode 23 and the drain electrode 24, as shown in FIG. 4.

In an exemplary embodiment, the pattern of the second metal layer may include a data signal line, and the source electrode may be interconnected with the data signal line to form an integral structure.

In an exemplary embodiment, the drain electrode 24 may extend to the photo-diode region so as to be connected with the first electrode of the photo-diode formed later.

Here, a thin film transistor as a switching apparatus in a photoelectric detection substrate has been formed on a glass substrate, and the thin film transistor with a bottom gate structure may include a gate electrode 21, an active layer 22, a source electrode 23 and a drain electrode 24.

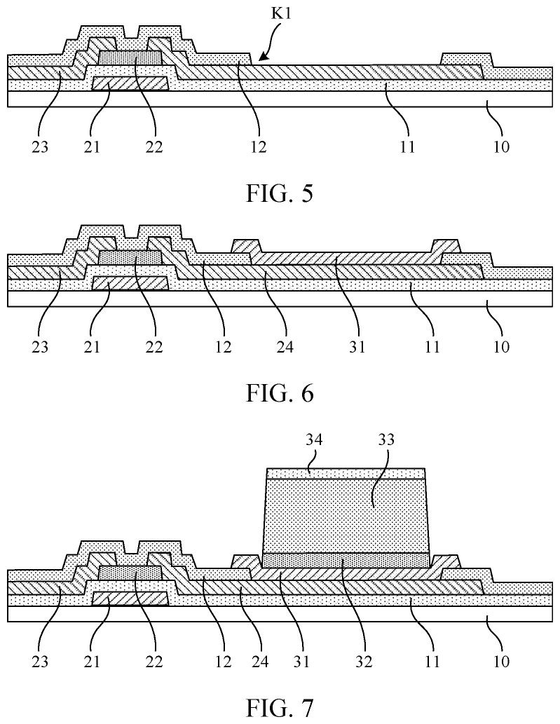

(4) A pattern of a second insulating layer is formed. In an exemplary embodiment, forming a pattern of a second insulating layer may include: depositing a second insulating thin film on the glass substrate on which the aforementioned patterns are formed, and patterning the second insulating thin film through a patterning process to form a pattern of the second insulating layer 12 covering the pattern of the second metal layer, wherein the second insulating layer 12 is provided with a first opening K1, and the second insulating layer 12 in the first opening K1 is etched away to expose part of the surface of the drain electrode 24, as shown in FIG. 5.

In an exemplary embodiment, the first opening K1 is configured such that the first electrode of a photo-diode to be formed later is connected to the drain electrode of the thin film transistor through the opening.

(5) A pattern of a third metal layer is formed. In an exemplary embodiment, forming a pattern of a third metal layer may include: depositing a third metal thin film on the glass substrate on which the aforementioned patterns are formed, and patterning the third metal thin film through a patterning process to form a pattern of the third metal layer, wherein the pattern of the third metal layer at least includes a first electrode 31 connected to a drain electrode 24 through a first opening K1, as shown in FIG. 6.

In an exemplary embodiment, the first electrode may use a high work function metal, such as molybdenum Mo, aluminum Al, copper Au, lead Pb or gold Au, etc.

(6) A pattern of a photo-diode is formed. In an exemplary embodiment, forming a pattern of a photo-diode may include: sequentially forming a doped thin film, an intrinsic thin film and a conductive thin film on a glass substrate on which the aforementioned patterns are formed, and patterning the conductive thin film, the intrinsic thin film and the doped thin film through a patterning process to form a stacked ohmic contact layer 32, an intrinsic layer 33 and a second electrode 34, wherein the ohmic contact layer 32 is disposed on one side of the first electrode 31 away from the glass substrate, the intrinsic layer 33 is disposed on one side of the ohmic contact layer 32 away from the glass substrate, and the second electrode 34 is disposed on one side of the intrinsic layer 33 away from the glass substrate, as shown in FIG. 7.

In an exemplary embodiment, the doped thin film may be formed by first depositing silicon-based semiconductors such as amorphous silicon, microcrystalline silicon or silicon germanium alloy, and then forming the doped thin film by doping treatment. In an exemplary embodiment, the doping treatment may use N-type ion implantation, and the formed ohmic contact layer 32 may be an N-type doped silicon-based semiconductor such as N-type doped amorphous silicon, N-type doped microcrystalline silicon or N-type doped silicon germanium alloy.

In an exemplary embodiment, the material of the intrinsic thin film may be silicon-based semiconductors such as amorphous silicon, microcrystalline silicon or silicon germanium alloy, and the material of the conductive thin film may be transparent conductive metal oxide materials with high work function, such as indium tin oxide (ITO) or indium zinc oxide (IZO).

So far, a Schottky photo-diode as an optical apparatus in the photoelectric detection substrate has been formed on the glass substrate, including a first electrode 31, an ohmic contact layer 32, an intrinsic layer 33 and a second electrode 34 disposed in sequence along the direction perpendicular to the glass substrate. The ohmic contact layer 32 is disposed on one side of the first electrode 31 away from the glass substrate and connected to the first electrode 31, the intrinsic layer 33 is disposed on one side of the ohmic contact layer 32 away from the glass substrate and connected to the ohmic contact layer 32, and the second electrode 34 is disposed on one side of the intrinsic layer 33 away from the glass substrate and connected to the intrinsic layer 33.

A Schottky Barrier Diode is a metal-semiconductor apparatus, and a Schottky barrier is formed between N-type semiconductor and metal. In the exemplary embodiment of this disclosure, because the intrinsic layer of amorphous silicon is weak N-type and the second electrode is metal oxide, thus the second electrode and the intrinsic layer form a Schottky contact, i.e., a Schottky junction, and the photo-diode is a Schottky photo-diode.

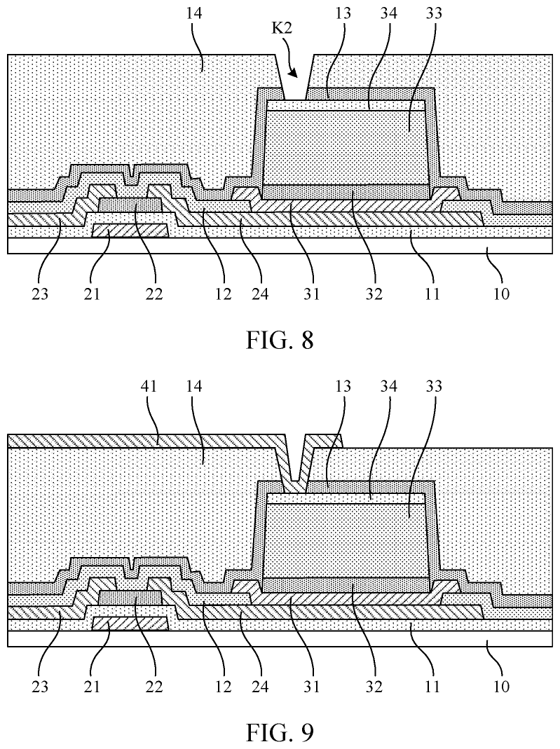

(7) Patterns of a third insulating layer and a planarization layer are formed. In an exemplary embodiment, forming patterns of the third insulating layer and the planarization layer may include: depositing a third insulating thin film on the glass substrate on which the aforementioned patterns are formed, then coating a planarization thin film, and patterning the planarization thin film and the third insulating thin film through a patterning process to form a third insulating layer 13 covering the photo-diode and a planarization layer 14 covering the third insulating layer 13, wherein the third insulating layer 13 and the planarization layer 14 are provided with a second opening K2, and the planarization thin film and the third insulating thin film in the second opening K2 are removed, exposing the surface of the second electrode 34, as shown in FIG. 8.

In an exemplary embodiment, the third insulating layer 13 is configured to protect the sidewall of the photo-diode, and the planarization layer 14 is configured to form a flush surface.

(8) A pattern of a fourth metal layer is formed. In an exemplary embodiment, forming a pattern of a fourth metal layer may include: depositing a fourth metal thin film on the glass substrate on which the aforementioned patterns are formed, and patterning the fourth metal thin film through a patterning process to form a pattern of the fourth metal layer on the planarization layer 14, wherein the pattern of the fourth metal layer at least includes an electrode lead 41 connected to a second electrode 34 through a second opening K2, as shown in FIG. 9.

(9) A pattern of a fourth insulating layer is formed. In an exemplary embodiment, forming a pattern of a fourth insulating layer may include: depositing a fourth insulating thin film on the glass substrate on which the aforementioned patterns are formed to form a fourth insulating layer 15 covering the aforementioned structure, as shown in FIG. 1.

In an exemplary embodiment, the fourth insulating layer 15 is configured to protect the photoelectric detection substrate, which may be referred to as an insulating protective layer.

At this point, the preparation of the photoelectric detection substrate according to the exemplary embodiment of the present disclosure is completed. And the photoelectric detection substrate includes an oxide thin film transistor and a Schottky photo-diode, wherein the oxide thin film transistor is used as a switching apparatus to control the readout of an electrical signal in the photo-diode, and the Schottky photo-diode is used as an optical apparatus to perform photoelectric conversion with incident light.

In an exemplary embodiment, the first insulating layer, the second insulating layer, the third insulating layer and the fourth insulating layer may be made of any one or more of silicon oxide (SiOx), silicon nitride (SiNx) and silicon nitride (SiON), and may be a single layer, a plurality of layers or a composite layer. The planarization layer may be made of an organic material such as resin. The first metal thin film and the second metal thin film may be made of a metal material, such as any one or more of silver (Ag), copper (Cu), aluminum (Al), titanium (Ti), and molybdenum (Mo), or an alloy material of the above metals, such as aluminum neodymium alloy (AlNd) or molybdenum niobium alloy (MoNb), and may be in a single-layer structure or multi-layer composite structure, such as Ti/Al/Ti.

It may be seen from the structure and preparation process of the photoelectric detection substrate described above that the photoelectric detection substrate provided by the exemplary embodiment of this disclosure adopts Schottky photo-diodes without P layer, which effectively improves the performance of photo-diodes and reduces the production cost. Because the photo-diode does not have a P layer, the absorption of light, especially of short-band light, by the P layer is avoided, reducing the light loss and effectively improves the performance of the photo-diode. Because the photo-diode does not have a P layer, the chamber pollution caused by the process of preparing the P layer is avoided, so that the amorphous silicon formed subsequently will not be doped, and the performance of the photo-diode is ensured, and the chamber cleaning process is not required frequently, thereby improving the production efficiency and reducing the production cost. Furthermore, because the photo-diode does not have a P layer, and the preparation of the photo-diode does not need a P-doping process, the thin film transistor may use an oxide thin film transistor, which not only has the advantages of low leakage current, high mobility and the like, but also can directly utilize the process and equipment for preparing the oxide thin film transistor without doping equipment and without modifying the process and equipment, thus being well compatible with the existing preparation process, having high production efficiency, low production cost and high yield rate.

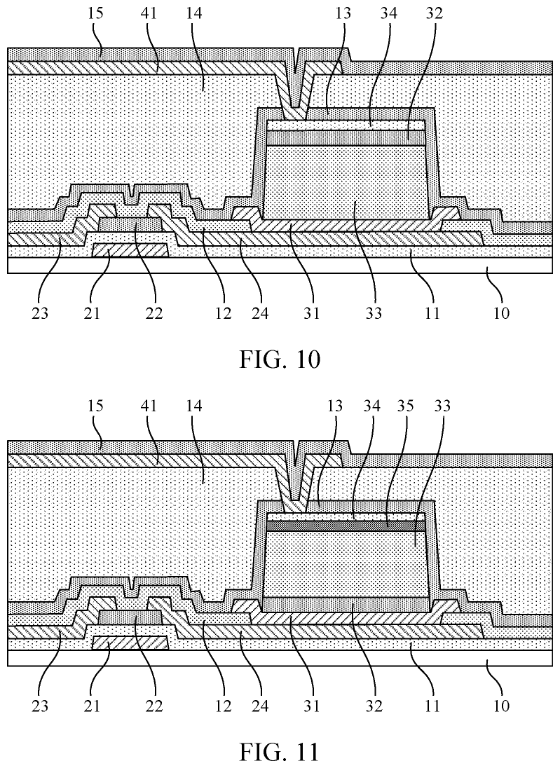

FIG. 10 is another schematic diagram of a structure of a photoelectric detection substrate in an exemplary embodiment of the present disclosure. In an exemplary embodiment, the photoelectric detection substrate includes a Schottky photo-diode and a thin film transistor disposed on a glass substrate 10, and the structure of the thin film transistor may be the same as that of the foregoing embodiment. As shown in FIG. 10, the Schottky photo-diode may include a first electrode 31, an intrinsic layer 33, an ohmic contact layer 32 and a second electrode 34 disposed in sequence along the direction perpendicular to the glass substrate, wherein the intrinsic layer 33 is disposed on one side of the first electrode 31 away from the glass substrate, the ohmic contact layer 32 is disposed on one side of the intrinsic layer 33 away from the glass substrate, and the second electrode 34 is disposed on one side of the ohmic contact layer 32 away from the glass substrate.

In an exemplary embodiment, the materials of the first electrode 31, the ohmic contact layer 32, the intrinsic layer 33, and the second electrode 34 may be the same as those in the previous embodiments, and the intrinsic layer 33, the ohmic contact layer 32, and the second electrode 34 of the photo-diode may be simultaneously formed through a same patterning process.

The manufacturing process of the photoelectric detection substrate of this exemplary embodiment is basically similar to that of the previous embodiments. The difference is that in the process of forming the photo-diode pattern, an intrinsic thin film, a doped thin film and a conductive thin film are deposited in sequence, and the conductive thin film, the doped thin film and the intrinsic thin film are patterned through a patterning process to form a stacked intrinsic layer 33, an ohmic contact layer 32 and a second electrode 34, wherein the intrinsic layer 33 is disposed on one side of the first electrode 31 away from the glass substrate, the ohmic contact layer 32 is disposed on one side of the intrinsic layer 33 away from the glass substrate, and the second electrode 34 is disposed on one side of the ohmic contact layer 32 away from the glass substrate.

In the exemplary embodiment of the present disclosure, because the intrinsic layer of amorphous silicon is weak N-type and the first electrode is a high work function metal, such as molybdenum or gold, therefore the first electrode and the intrinsic layer form Schottky contact, and the photo-diode is a Schottky photo-diode.

In the photoelectric detection substrate of this exemplary embodiment, a Schottky photo-diode without a P layer is adopted, which effectively improves the performance of the photo-diode and reduces the production cost.

FIG. 11 is another schematic diagram of a structure of a photoelectric detection substrate in an exemplary embodiment of the present disclosure. In an exemplary embodiment, the photoelectric detection substrate includes a Schottky photo-diode and a thin film transistor disposed on a glass substrate 10, and the structure of the thin film transistor may be the same as that of the foregoing embodiment. As shown in FIG. 11, the Schottky photo-diode may include a first electrode 31, an ohmic contact layer 32, an intrinsic layer 33, a barrier layer 35 and a second electrode 34 disposed in sequence along the direction perpendicular to the glass substrate. The ohmic contact layer 32 is disposed on one side of the first electrode 31 away from the glass substrate, the intrinsic layer 33 is disposed on one side of the ohmic contact layer 32 away from the glass substrate, the barrier layer 35 is disposed on one side of the intrinsic layer 33 away from the glass substrate, and the second electrode 34 is disposed on one side of the barrier layer 35 away from the glass substrate.

In an exemplary embodiment, the materials of the first electrode 31, the ohmic contact layer 32, the intrinsic layer 33, and the second electrode 34 may be the same as those in the previous embodiments, and the barrier layer 35 may use an insulating layer in a semiconductor manufacturing process, including any one or more of silicon oxide (SiOx), silicon nitride (SiNx), silicon oxynitride (SiON), and aluminum oxide (Al2O3), and may be a single layer, a multi-layer or a composite layer.

In an exemplary embodiment, a thickness of a barrier layer 35 is about 1 nm to 5 nm.

In an exemplary embodiment, the ohmic contact layer 32, the intrinsic layer 33, the barrier layer 35, and the second electrode 34 of the photo-diode may be simultaneously formed through the same patterning process.

The manufacturing process of the photoelectric detection substrate of this exemplary embodiment is basically similar to that of the previous embodiments. The difference is that in the process of forming the pattern of the photo-diode, a doped thin film, an intrinsic thin film, a barrier thin film and a conductive thin film are deposited in sequence, and the conductive thin film, barrier thin film, intrinsic thin film and doped thin film are patterned through a patterning process to form a stacked ohmic contact layer 32, intrinsic layer 33, barrier layer 35 and second electrode 34. The ohmic contact layer 32 is disposed on one side of the first electrode 31 away from the glass substrate, the intrinsic layer 33 is disposed on one side of the ohmic contact layer 32 away from the glass substrate, the barrier layer 35 is disposed on one side of the intrinsic layer 33 away from the glass substrate, and the second electrode 34 is disposed on one side of the barrier layer 35 away from the glass substrate.

In an exemplary embodiment, the barrier layer may be deposited by plasma enhanced chemical vapor deposition (PECVD), atomic layer deposition (ALD), thermal oxidation or chemical oxidation, etc.

In the photoelectric detection substrate of this exemplary embodiment, in addition to a Schottky photo-diode without P layer being adopted, which effectively improves the performance of the photo-diode and reduces the production cost, a barrier layer is also provided in the Schottky photo-diode between the intrinsic layer of amorphous silicon material and the second electrode of metal oxide transparent conductive material, forming a metal oxide-barrier layer-semiconductor (MIS) structure. Wherein, the MIS structure is used to suppress interface diffusion, which reduces amorphous silicon interface defects and bulk defects, inhibits carrier thermally assisted tunneling, lowers dark-state current and helps to reduce noise. Furthermore, because the barrier layer is deposited before the metal oxide, the atomic diffusion in the metal oxide deposition process may be avoided, and the interface diffusion may be further suppressed, which further reduces the interface defects and bulk defects of amorphous silicon.

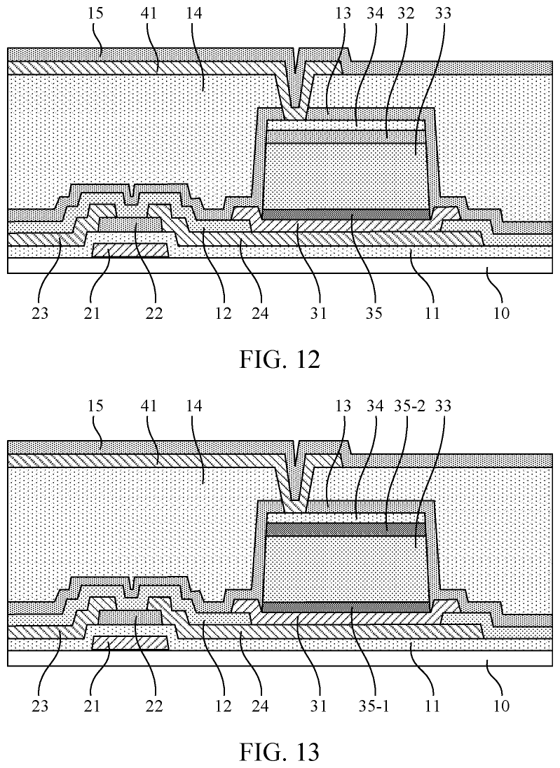

FIG. 12 is another schematic diagram of a structure of a photoelectric detection substrate in an exemplary embodiment of the present disclosure. In an exemplary embodiment, the photoelectric detection substrate includes a Schottky photo-diode and a thin film transistor disposed on a glass substrate 10, and the structure of the thin film transistor may be the same as that of the foregoing embodiment. As shown in FIG. 12, the Schottky photo-diode may include a first electrode 31, a barrier layer 35, an intrinsic layer 33, an ohmic contact layer 32 and a second electrode 34 disposed in sequence along the direction perpendicular to the glass substrate. The barrier layer 35 is disposed on one side of the first electrode 31 away from the glass substrate, the intrinsic layer 33 is disposed on one side of the barrier layer 35 away from the glass substrate, the ohmic contact layer 32 is disposed on one side of the intrinsic layer 33 away from the glass substrate, and the second electrodes 34 is disposed on one side of the ohmic contact layer 32 away from the glass substrate.

In an exemplary embodiment, the materials of the first electrode 31, the ohmic contact layer 32, the intrinsic layer 33, and the second electrode 34 may be the same as those in the previous embodiments, and the barrier layer 35 may any one or more of silicon oxide (SiOx), silicon nitride (SiNx), silicon oxynitride (SiON), and aluminum oxide (Al2O3), and may be a single layer, a multi-layer or a composite layer.

In an exemplary embodiment, a thickness of a barrier layer 35 is about 1 nm to 5 nm.

In an exemplary embodiment, the barrier layer 35, the intrinsic layer 33, the ohmic contact layer 32, and the second electrode 34 of the photo-diode may be simultaneously formed through the same patterning process.

The manufacturing process of the photoelectric detection substrate of this exemplary embodiment is basically similar to that of the previous embodiments. The difference is that in the process of forming the pattern of the photo-diode, a barrier thin film, an intrinsic thin film, a doped thin film and a conductive thin film are deposited in sequence, and the conductive thin film, the doped thin film, the intrinsic thin film and the barrier thin film are patterned through a patterning process to form a stacked barrier layer 35, intrinsic layer 33, an ohmic contact layer 32 and a second electrode 34. The barrier layer 35 is disposed on one side of the first electrode 31 away from the glass substrate, the intrinsic layer 33 is disposed on one side of the barrier layer 35 away from the glass substrate, the ohmic contact layer 32 is disposed on one side of the intrinsic layer 33 away from the glass substrate, and the second electrodes 34 is disposed on one side of the ohmic contact layer 32 away from the glass substrate.

In the photoelectric detection substrate of this exemplary embodiment, in addition to a Schottky photo-diode without P layer being adopted, which effectively improves the performance of the photo-diode and reduces the production cost, a barrier layer is also provided in the Schottky photo-diode between the first electrode 31 of metal material and the intrinsic layer 33 of amorphous silicon material, forming a metal-insulating layer-semiconductor (MIS) structure. Wherein, the MIS structure is used to improve interface diffusion, which reduces amorphous silicon interface defects and bulk defects, inhibits carrier tunneling, lowers dark-state current and helps to reduce noise. Furthermore, because the barrier layer is deposited before the amorphous silicon, atomic diffusion of metal may be avoided, interface diffusion may be further suppressed, and the interface defects and bulk defects of amorphous silicon are further reduced.

FIG. 13 is another schematic diagram of a structure of a photoelectric detection substrate in an exemplary embodiment of the present disclosure. In an exemplary embodiment, the photoelectric detection substrate includes a Schottky photo-diode and a thin film transistor disposed on a glass substrate 10, and the structure of the thin film transistor may be the same as that of the foregoing embodiment. As shown in FIG. 13, the Schottky photo-diode may include a first electrode 31, a first barrier layer 35-1, an intrinsic layer 33, a second barrier layer 35-2 and a second electrode 34 disposed in sequence along the direction perpendicular to the glass substrate. The first barrier layer 35-1 is disposed on one side of the first electrode 31 away from the glass substrate, the intrinsic layer 33 is disposed on one side of the first barrier layer 35-1 away from the glass substrate, the second barrier layer 35-2 is disposed on one side of the intrinsic layer 33 away from the glass substrate, and the second electrode 34 is disposed on one side of the second barrier layer 35-2 away from the glass substrate. That is, the first barrier layer 35-1 is provided between the first electrode 31 and the intrinsic layer 33, and the second barrier layer 35-2 is provided between the intrinsic layer 33 and the second electrode 34.

In an exemplary embodiment, the materials of the first electrode 31, the intrinsic layer 33, and the second electrode 34 may be the same as those in the previous embodiments, and the barrier layer 35 may any one or more of silicon oxide (SiOx), silicon nitride (SiNx), silicon oxynitride (SiON), and aluminum oxide (Al2O3), and may be a single layer, a multi-layer or a composite layer.

In an exemplary embodiment, the thickness of the first barrier layer 35-1 and the second barrier layer 35-2 may be about 1 nm to 5 nm.

In an exemplary embodiment, the first barrier layer 35-1, the intrinsic layer 33, the second barrier layer 35-2, and the second electrode 34 of the photo-diode may be simultaneously formed through the same patterning process.

The manufacturing process of the photoelectric detection substrate of this exemplary embodiment is basically similar to that of the previous embodiments. The difference is that in the process of forming the pattern of the photo-diode, a first barrier thin film, an intrinsic thin film, a second barrier thin film and a conductive thin film are deposited in sequence, and the conductive thin film, the second barrier thin film, the intrinsic thin film and the first barrier thin film are patterned through a patterning process to form a stacked first barrier layer 35-1, intrinsic layer 33, an second barrier layer 35-32 and a second electrode 34. The first barrier layer 35-1 is disposed on one side of the first electrode 31 away from the glass substrate, the intrinsic layer 33 is disposed on one side of the first barrier layer 35-1 away from the glass substrate, the second barrier layer 35-2 is disposed on one side of the intrinsic layer 33 away from the glass substrate, and the second electrode 34 is disposed on one side of the second barrier layer 35-2 away from the glass substrate.

In the photoelectric detection substrate of this exemplary embodiment, in addition to a Schottky photo-diode without P layer being adopted, which effectively improves the performance of the photo-diode and reduces the production cost, barrier layers are also provided in the Schottky photo-diode. The first barrier layer is disposed between the first electrode 31 of metal material and the intrinsic layer 33 of amorphous silicon material, forming a metal-insulating layer-semiconductor structure, and the second barrier layer 35-2 is disposed between the intrinsic layer of amorphous silicon material and the second electrode of metal oxide transparent conductive material, forming a metal oxide-barrier layer-semiconductor structure. Wherein, the MIS structure is used to improve interface diffusion, which reduces amorphous silicon interface defects and bulk defects, inhibits carrier tunneling, lowers dark-state current and helps to reduce noise. Furthermore, because the first barrier layer is deposited before the amorphous silicon, atomic diffusion of metal may be avoided, and because the second barrier layer is deposited before the metal oxide, atomic diffusion during metal oxide deposition may be avoided, the interface diffusion may be further suppressed, and the interface defects and bulk defects of amorphous silicon are further reduced.

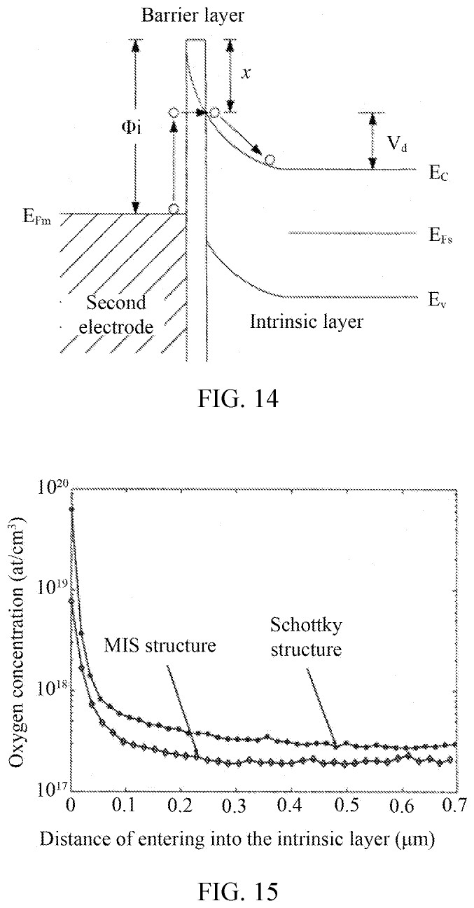

FIG. 14 is a schematic diagram of carrier transport in an MIS structure, in which E_{Fm} is Fermi level of second electrode (ITO), E_{Fs} is Fermi level of intrinsic layer (amorphous silicon), E_{C} is conduction band of intrinsic layer, E_{V} is valence band of intrinsic layer, V_{d} is built-in electric field bias, χ is electron affinity, and φᵢ is potential barrier. As shown in FIG. 14, by providing the barrier layer between the intrinsic layer and the second electrode, the barrier height can be greatly increased, electrons need to tunnel through the insulating layer and enter into the amorphous silicon layer, and thermal excitation affected by Schottky barrier and thermally assisted tunneling caused by amorphous silicon interface defects are suppressed, thus achieving the effect of reducing dark state current.

FIG. 15 is a comparison diagram of oxygen content between an MIS structure and a Schottky structure. The experimental results show that the oxygen content in the intrinsic layer is obviously reduced due to the barrier layer provided between the intrinsic layer and the second electrode, which can effectively reduce the interfacial defects and bulk defects of the intrinsic layer, as shown in FIG. 15.

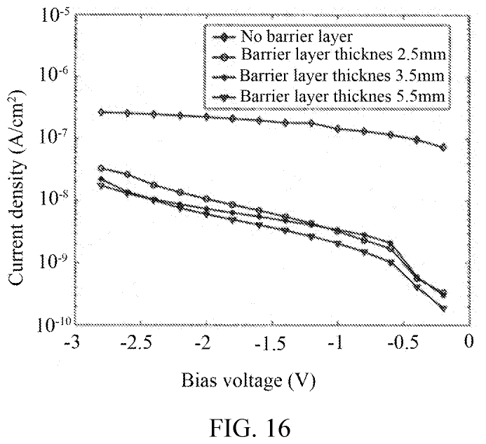

FIG. 16 is a comparison diagram of leakage current between an MIS structure and a Schottky structure. The experimental results show that by providing the barrier layer between the intrinsic layer and the second electrode, the leakage current is obviously reduced, and with the increase of the thickness of the barrier layer, the leakage current may be further reduced, but the leakage current is not greatly reduced, as shown in FIG. 16.

An embodiment of the present disclosure further provides a method for preparing the photoelectric detection substrate of any of the foregoing exemplary embodiments. In an exemplary embodiment, the method for preparing a photoelectric detection substrate may include following steps.

Forming an electronic apparatus and an optical apparatus on a glass substrate, wherein the optical apparatus is a Schottky photo-diode.

In an exemplary embodiment, forming a Schottky photo-diode on a glass substrate may include:

forming a first electrode; and sequentially forming an ohmic contact layer, an intrinsic layer and a second electrode, wherein the ohmic contact layer is disposed on one side of the first electrode away from the glass substrate, the intrinsic layer is disposed on one side of the ohmic contact layer away from the glass substrate, and the second electrode is disposed on one side of the intrinsic layer away from the glass substrate.

In an exemplary embodiment, forming a Schottky photo-diode on a glass substrate may include:

forming a first electrode; and sequentially forming an intrinsic layer, an ohmic contact layer and a second electrode; wherein the intrinsic layer is disposed on one side of the first electrode away from the glass substrate, the ohmic contact layer is disposed on one side of the intrinsic layer away from the glass substrate, and the second electrode is disposed on one side of the ohmic contact layer away from the glass substrate.

In an exemplary embodiment, forming a Schottky photo-diode on a glass substrate may include:

forming a first electrode; and sequentially forming an ohmic contact layer, an intrinsic layer, a barrier layer and a second electrode; wherein the ohmic contact layer is disposed on one side of the first electrode away from the glass substrate, the intrinsic layer is disposed on one side of the ohmic contact layer away from the glass substrate, the barrier layer is disposed on one side of the intrinsic layer away from the glass substrate, and the second electrode is disposed on one side of the barrier layer away from the glass substrate.

In an exemplary embodiment, forming a Schottky photo-diode on a glass substrate may include:

forming a first electrode; and sequentially forming a barrier layer, an intrinsic layer, an ohmic contact layer and a second electrode; wherein the barrier layer is disposed on one side of the first electrode away from the glass substrate, the intrinsic layer is disposed on one side of the barrier layer away from the glass substrate, the ohmic contact layer is disposed on one side of the intrinsic layer away from the glass substrate, and the second electrode is disposed on one side of the ohmic contact layer away from the glass substrate.

In an exemplary embodiment, forming a Schottky photo-diode on a glass substrate may include:

forming a first electrode; and sequentially forming a first barrier layer, an intrinsic layer, a second barrier layer and a second electrode; wherein the first barrier layer is disposed on one side of the first electrode away from the glass substrate, the intrinsic layer is disposed on one side of the first barrier layer away from the glass substrate, the second barrier layer is disposed on one side of the intrinsic layer away from the glass substrate, and the second electrode is disposed on one side of the second barrier layer away from the glass substrate.

In an exemplary embodiment, the material of the first electrode includes molybdenum, aluminum, copper, lead or gold, and the material of the second electrode includes indium tin oxide or indium zinc oxide; the material of the ohmic contact layer includes N-type doped amorphous silicon, N-type doped microcrystalline silicon or N-type doped silicon germanium alloy, and the material of the intrinsic layer includes amorphous silicon, microcrystalline silicon or silicon germanium alloy.

In an exemplary embodiment, the material of the barrier layer includes silicon oxide, silicon nitride or silicon oxynitride, and the thickness of the barrier layer is 1 nm to 5 nm.

In an exemplary embodiment, the electronic apparatus includes an oxide thin film transistor.

The content of the preparation method for the photoelectric detection substrate in the embodiment of the present disclosure has been described in detail in the preparation process for the photoelectric detection substrate, and will not be repeated here.

According to the preparation method of the photoelectric detection substrate provided by the disclosure, a Schottky photo-diode without a P layer is adopted, which effectively improves the performance of the photo-diode and reduces the production cost. Because the photo-diode does not have a P layer, the absorption of light, especially of short-band light, by the P layer is avoided, reducing the light loss and effectively improves the performance of the photo-diode. Because the photo-diode does not have a P layer, the chamber pollution caused by the process of preparing the P layer is avoided, so that the amorphous silicon formed subsequently will not be doped, and the performance of the photo-diode is ensured, and the chamber cleaning process is not required frequently, thereby improving the production efficiency and reducing the production cost. Furthermore, because the photo-diode does not have a P layer, and the preparation of the photo-diode does not need a P-doping process, the thin film transistor may be an oxide thin film transistor, which not only has the advantages of low leakage current, high mobility and the like, but also can directly utilize the process and equipment for preparing the oxide thin film transistor without doping equipment and without modifying the process and equipment, thus being well compatible with the existing preparation process, having high production efficiency, low production cost and high yield rate.

The present disclosure further provides a photoelectric detection apparatus including the photoelectric detection substrate in the aforementioned exemplary embodiments.

Although implementations disclosed in the present disclosure are as the above, the described contents are only implementations used for facilitating understanding the present disclosure, and are not used to limit the present invention. Any person skilled in the art to which the present disclosure pertains may make any modification and variation in forms and details of implementation without departing from the spirit and scope of the present disclosure, however, the patent protection scope of the present disclosure shall still be subject to the scope defined by the appended claims.

What is claimed is:

1. A photoelectric detection substrate, comprising:
a glass substrate, and an electronic apparatus and an optical apparatus disposed on the glass substrate, wherein the optical apparatus comprises a Schottky photo-diode.

2. The photoelectric detection substrate of claim 1, wherein
the Schottky photo-diode comprises a first electrode, an ohmic contact layer disposed on one side of the first electrode away from the glass substrate, an intrinsic layer disposed on one side of the ohmic contact layer away from the glass substrate and a second electrode disposed on one side of the intrinsic layer away from the glass substrate; or,
the Schottky photo-diode comprises a first electrode, an intrinsic layer disposed on one side of the first electrode away from the glass substrate, an ohmic contact layer disposed on one side of the intrinsic layer away from the glass substrate, and a second electrode disposed on one side of the ohmic contact layer away from the glass substrate.

3. The photoelectric detection substrate of claim 1, wherein
the Schottky photo-diode comprises a first electrode, an ohmic contact layer disposed on one side of the first electrode away from the glass substrate, an intrinsic layer disposed on one side of the ohmic contact layer away from the glass substrate, a barrier layer disposed on one side of the intrinsic layer away from the glass substrate and a second electrode disposed on one side of the barrier layer away from the glass substrate; or,
the Schottky photo-diode comprises a first electrode, a barrier layer disposed on one side of the first electrode away from the glass substrate, an intrinsic layer disposed on one side of the barrier layer away from the glass substrate, an ohmic contact layer disposed on one side of the intrinsic layer away from the glass substrate, and a second electrode disposed on one side of the ohmic contact layer away from the glass substrate.

4. The photoelectric detection substrate of claim 1, wherein the Schottky photo-diode comprises a first electrode, a first barrier layer disposed on one side of the first electrode away from the glass substrate, an intrinsic layer disposed on one side of the first barrier layer away from the glass substrate, a second barrier layer disposed on one side of the intrinsic layer away from the glass substrate, and a second electrode disposed on one side of the second barrier layer away from the glass substrate.

5. The photoelectric detection substrate of claim 2, wherein
a material of the first electrode comprises molybdenum, aluminum, copper, lead or gold; a material of the second electrode comprises indium tin oxide or indium zinc oxide;
a material of the ohmic contact layer comprises N-type doped amorphous silicon, N-type doped microcrystalline silicon or N-type doped silicon germanium alloy;
and a material of the intrinsic layer comprises amorphous silicon, microcrystalline silicon or silicon germanium alloy.

6. The photoelectric detection substrate of claim 3, wherein a material of the barrier layer comprises silicon oxide, silicon nitride, silicon oxynitride or aluminum oxide.

7. The photoelectric detection substrate of claim 3, wherein a thickness of the barrier layer is 1 nm to 5 nm.

8. The photoelectric detection substrate of claim 1, wherein the electronic apparatus comprises an oxide thin film transistor.

9. A photoelectric detection apparatus, comprising a photoelectric detection substrate, wherein the photoelectric detection substrate comprises a glass substrate, and an electronic apparatus and an optical apparatus disposed on the glass substrate, wherein the optical apparatus comprises a Schottky photo-diode.

10. The photoelectric detection apparatus of claim 9, wherein
the Schottky photo-diode comprises a first electrode, an ohmic contact layer disposed on one side of the first electrode away from the glass substrate, an intrinsic layer disposed on one side of the ohmic contact layer away from the glass substrate and a second electrode disposed on one side of the intrinsic layer away from the glass substrate; or
the Schottky photo-diode comprises a first electrode, an intrinsic layer disposed on one side of the first electrode away from the glass substrate, an ohmic contact layer disposed on one side of the intrinsic layer away from the glass substrate, and a second electrode disposed on one side of the ohmic contact layer away from the glass substrate.

11. The photoelectric detection apparatus of claim 9, wherein
the Schottky photo-diode comprises a first electrode, an ohmic contact layer disposed on one side of the first electrode away from the glass substrate, an intrinsic layer disposed on one side of the ohmic contact layer away from the glass substrate, a barrier layer disposed on one side of the intrinsic layer away from the glass substrate and a second electrode disposed on one side of the barrier layer away from the glass substrate; or,
the Schottky photo-diode comprises a first electrode, a barrier layer disposed on one side of the first electrode away from the glass substrate, an intrinsic layer disposed on one side of the barrier layer away from the glass substrate, an ohmic contact layer disposed on one side of the intrinsic layer away from the glass substrate, and a second electrode disposed on one side of the ohmic contact layer away from the glass substrate.

12. The photoelectric detection apparatus of claim 9, wherein the Schottky photo-diode comprises a first electrode, a first barrier layer disposed on one side of the first electrode away from the glass substrate, an intrinsic layer disposed on one side of the first barrier layer away from the glass substrate, a second barrier layer disposed on one side of the intrinsic layer away from the glass substrate, and a second electrode disposed on one side of the second barrier layer away from the glass substrate.

13. The photoelectric detection apparatus of claim 11, wherein
a material of the first electrode comprises molybdenum, aluminum, copper, lead or gold; a material of the second electrode comprises indium tin oxide or indium zinc oxide;
a material of the ohmic contact layer comprises N-type doped amorphous silicon, N-type doped microcrystalline silicon or N-type doped silicon germanium alloy;
a material of the intrinsic layer comprises amorphous silicon, microcrystalline silicon or silicon germanium alloy;
and a material of the barrier layer comprises silicon oxide, silicon nitride, silicon oxynitride or aluminum oxide.

14. The photoelectric detection apparatus of claim 9, wherein the electronic apparatus comprises an oxide thin film transistor.

15. A preparation method for a photoelectric detection substrate, comprising:
forming an electronic apparatus and an optical apparatus on a glass substrate, wherein the optical apparatus comprise a Schottky photo-diode.

16. The preparation method of claim 15, wherein forming the optical apparatus comprising the Schottky photo-diode on the glass substrate comprises:
forming a first electrode; and sequentially forming an ohmic contact layer, an intrinsic layer and a second electrode, wherein the ohmic contact layer is disposed on one side of the first electrode away from the glass substrate, the intrinsic layer is disposed on one side of the ohmic contact layer away from the glass substrate, and the second electrode is disposed on one side of the intrinsic layer away from the glass substrate; or
forming a first electrode; and sequentially forming an intrinsic layer, an ohmic contact layer and a second electrode; wherein the intrinsic layer is disposed on one side of the first electrode away from the glass substrate, the ohmic contact layer is disposed on one side of the intrinsic layer away from the glass substrate, and the second electrode is disposed on one side of the ohmic contact layer away from the glass substrate.

17. The preparation method of claim 15, wherein forming the optical apparatus comprising the Schottky photo-diode on the glass substrate comprises:
forming a first electrode; and sequentially forming an ohmic contact layer, an intrinsic layer, a barrier layer and a second electrode; wherein the ohmic contact layer is disposed on one side of the first electrode away from the glass substrate, the intrinsic layer is disposed on one side of the ohmic contact layer away from the glass substrate, the barrier layer is disposed on one side of the intrinsic layer away from the glass substrate, and the second electrode is disposed on one side of the barrier layer away from the glass substrate; or
forming a first electrode; and sequentially forming a barrier layer, an intrinsic layer, an ohmic contact layer and a second electrode; wherein the barrier layer is disposed on one side of the first electrode away from the glass substrate, the intrinsic layer is disposed on one side of the barrier layer away from the glass substrate, the ohmic contact layer is disposed on one side of the intrinsic layer away from the glass substrate, and the second electrode is disposed on one side of the ohmic contact layer away from the glass substrate.

18. The preparation method of claim 15, wherein forming the optical apparatus comprising the Schottky photo-diode on the glass substrate comprises:
forming a first electrode; and sequentially forming a first barrier layer, an intrinsic layer, a second barrier layer and a second electrode, wherein the first barrier layer is disposed on one side of the first electrode away from the glass substrate, the intrinsic layer is disposed on one side of the first barrier layer away from the glass substrate, the second barrier layer is disposed on one side of the intrinsic layer away from the glass substrate, and the second electrode is disposed on one side of the second barrier layer away from the glass substrate.

19. The preparation method of claim 16, wherein a material of the first electrode comprises molybdenum, aluminum, copper, lead or gold;
a material of the second electrode comprises indium tin oxide or indium zinc oxide;
a material of the ohmic contact layer comprises N-type doped amorphous silicon, N-type doped microcrystalline silicon or N-type doped silicon germanium alloy;
and a material of the intrinsic layer comprises amorphous silicon, microcrystalline silicon or silicon germanium alloy.

20. The preparation method of claim 17, wherein a material of the barrier layer comprises silicon oxide, silicon nitride, silicon oxynitride or aluminum oxide, the barrier layer is deposited by plasma enhanced chemical vapor deposition, atomic layer deposition, thermal oxidation or chemical oxidation;
and a thickness of the barrier layer is 1 nm to 5 nm.
